(19) United States
(12) Patent Application Publication
(10) Pub. No.: US 2026/0321200 A1
(43) Pub. Date: Oct. 15, 2026

(54) Displays with Distributed Thin-Film Transistor Drivers

(71) Applicant: Apple Inc., Cupertino, CA (US)

(72) Inventors: Chuang Qian, Santa Clara, CA (US); Warren S. Rieutort-Louis, Cupertino, CA (US); Majid Gharghi, San Carlos, CA (US); Cheng-Chih Hsieh, Santa Clara, CA (US); Daniel de Godoy Peixoto, Austin, TX (US); Abbas Jamshidi Roudbari, Saratoga, CA (US); Ting-Kuo Chang, San Jose, CA (US); Shih Chang Chang, Cupertino, CA (US); Michael H. Lim, Sunnyvale, CA (US); David A. Doyle, Needham, MA (US); Weijun Yao, Saratoga, CA (US); David S. Hum, Sunnyvale, CA (US); Jiayi Jin, Redwood City, CA (US); Abhijeet S. Bagal, Sunnyvale, CA (US)

(21) Appl. No.: 19/555,501

(22) Filed: Mar. 3, 2026

Related U.S. Application Data
(60) Provisional application No. 63/786,073, filed on Apr. 9, 2025.

(51) Int. Cl. G09G 3/3225; H10K 59/121; H10K 59/131; H10K 59/65

(52) U.S. Cl. CPC G09G 3/3225; H10K 59/1213; H10K 59/131; H10K 59/65; G09G 2320/0233; G09G 2360/148

(57) ABSTRACT

An electronic device may include a display and an optical sensor formed underneath the display. A modified region of the display may form a window that overlaps the sensor. The window in the display may be formed by removing thin-film transistor (TFT) drivers from pixels in the window and distributing those TFT drivers uniformly throughout the display and/or edge(s) of a light-emitting area of the display. The distributed TFT drivers may have dedicated row drivers and may be driven with a different frequency from the rest of the display. There may be one or more distributed TFT drivers to remotely drive one or more emissive subpixels. Alternatively or additionally, the distributed TFT drivers may be coupled to dedicated power domains. One or more of the distributed TFT drivers may be coupled to one or more of the pixels in the window.

This application claims the benefit of U.S. provisional patent application No. 63/786,073, filed Apr. 9, 2025, which is hereby incorporated by reference herein in its entirety.

### BACKGROUND

This relates generally to electronic devices, and, more particularly, to electronic devices with displays.

Electronic devices often include displays. For example, an electronic device may have a light-emitting diode (LED) display based on light-emitting diode pixels. In this type of display, each pixel includes a light-emitting diode and thin-film transistors for controlling application of a signal to the light-emitting diode to produce light.

There is a trend towards borderless electronic devices with a full-face display. However, it may be difficult to incorporate sensors such as cameras, ambient light sensors, and proximity sensors within full-face display devices.

### SUMMARY

An electronic device may include a plurality of pixels arranged in a light-emitting area. Each one of the plurality of pixels may be an emissive portion and a thin-film transistor driver that controls the emissive portion of that pixel. The electronic device may further include a window in the plurality of pixels that includes a subset of the emissive portions and that is free of thin-film transistor drivers, distributed thin-film transistor drivers that are coupled to the subset of the emissive portions to control the subset of the emissive portions, and a camera that operates through the window in the plurality of pixels.

An electronic device may include a light sensor, and a display comprising a plurality of pixels that form a light-emitting area. The light sensor may sense light that passes through the display, the display may have a first region that overlaps the light sensor and a second region that does not overlap the light sensor, and the plurality of pixels in the first region may include emissive portions that are coupled to distributed thin-film transistor drivers along an edge of the light-emitting area.

An electronic device may include a plurality of pixels arranged in a light-emitting area. Each one of the plurality of pixels may include an emissive subpixel and a thin-film transistor driver that controls the emissive subpixel of that pixel. The electronic device may further include a window in the plurality of pixels that includes a subset of the emissive subpixels and that is free of thin-film transistor drivers, and distributed thin-film transistor drivers that are coupled to the subset of the emissive subpixels to control the subset of the emissive subpixels. The distributed thin-film transistor drivers may be formed along an edge of the light-emitting area. The electronic device may further include a sensor that operates through the window in the plurality of pixels.

### BRIEF DESCRIPTION OF THE DRAWINGS

FIG. 1 is a schematic diagram of an illustrative electronic device having a display and one or more sensors in accordance with some embodiments.

FIG. 2 is a schematic diagram of an illustrative display with light-emitting elements in accordance with some embodiments.

FIG. 3 is a diagram of an illustrative display pixel circuit in accordance with some embodiments.

FIG. 4 is a cross-sectional side view of an illustrative display that overlaps a sensor in accordance with some embodiments.

FIGS. 5A-5E are top views of illustrative displays showing possible positions for locally modified regions in accordance with some embodiments.

FIG. 6 is a side view of an illustrative display having a window with removed thin-film transistor drivers in accordance with some embodiments.

FIG. 7 is a top view of an illustrative display having a distributed thin-film transistor driver in a light-emitting area in accordance with some embodiments.

FIG. 8 is a top view of an illustrative display having a distributed thin-film transistor driver along an edge of a light-emitting area in accordance with some embodiments.

FIG. 9 is a top view of an illustrative display having one or more dedicated emission drivers for distributed thin-film transistor drivers in accordance with some embodiments.

FIG. 10 is an illustrative timing diagram for a display with a sensor window in accordance with some embodiments.

FIGS. 11A-11D are top views of illustrative thin-film transistor drivers coupled to one or more pixels in accordance with some embodiments.

FIG. 12 is a top view of an illustrative display having one or more dedicated power domains and/or row drivers for distributed thin-film transistor drivers in accordance with some embodiments.

### DETAILED DESCRIPTION

An electronic device may include a light sensor and a display through which the light sensor receives light. For example, the light sensor may be a camera, ambient light sensor, or other sensor that receives light through the display layers of the display. The display may include an array of pixels, and each pixel may include pixel circuitry. The array is generally formed so that each pixel has the same aperture as the other pixels in the array. However, light may be diffracted and/or blocked by the pixel circuitry and therefore interfere with measurements taken by the underlying light sensor. Therefore, the pixel array may be modified in regions that overlap the light sensor.

For example, the pixels regions that overlap the light sensor may be given different characteristics (e.g., different wiring characteristics or different display layer characteristics) that affect the reflection of ambient light that passes through the display, which may reduce the amount of diffraction. In some embodiments, each pixel may include thin-film transistor (TFT) pixel drivers that drive emissive portions of the pixel to emit light. To increase the transparency of the pixels regions that overlap the light sensor, the TFT pixel drivers of the pixels in those regions may be formed remotely from the regions. As examples, the TFT pixel drivers may be distributed within the active area and/or distributed along an edge of the active area.

Alternatively or additionally, the pixels in the regions overlapping the sensor may be driven with a different frequency from the rest of the display and/or may be driven with a different amount of power from the rest of the display to improve display uniformity. In this way, a display may have a window in which TFT pixel drivers are absent (e.g., relocated to another portion of the display) to accommodate an underlying sensor, while maintaining a uniform appearance.

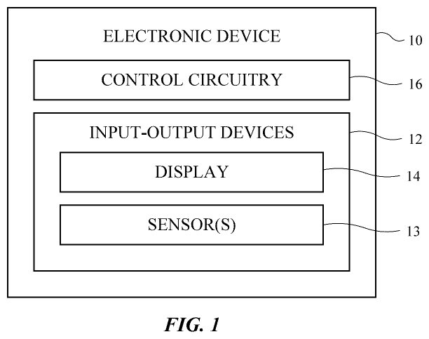

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output devices in device 10 such as input-output devices 12 may be used to allow data to be supplied to device 10 and to allow data to be provided from device 10 to external devices. Input-output devices 12 may include buttons, joysticks, scrolling wheels, touch pads, keypads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors, fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be a light-emitting diode display (e.g., an organic light-emitting diode (OLED) display) or may be a display based on other types of display technology (e.g., a liquid crystal display, a microLED display, and/or other suitable display). Device configurations in which display 14 is a light-emitting diode display are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

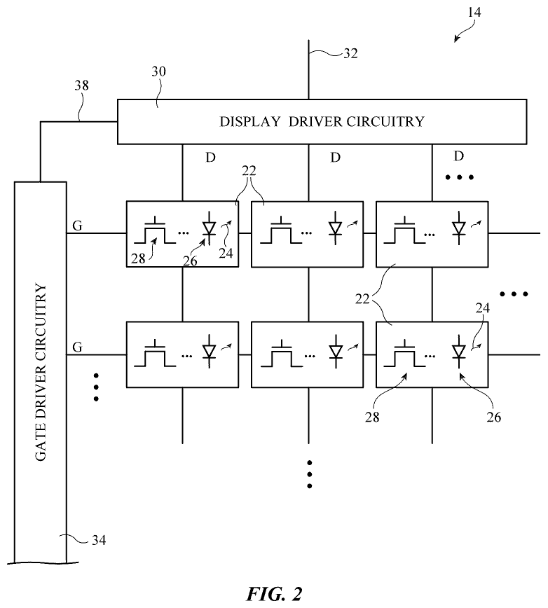

A top view of a portion of display 14 is shown in FIG. 2. As shown in FIG. 2, display 14 may have an array of pixels 22 formed on a substrate. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may include a light-emitting diode 26 that emits light 24 under the control of a pixel control circuit formed from thin-film transistor circuitry such as thin-film transistors 28 and thin-film capacitors. Thin-film transistors 28 may be polysilicon thin-film transistors, semiconducting-oxide thin-film transistors such as indium zinc gallium oxide (IGZO) transistors, or thin-film transistors formed from other semiconductors. Pixels 22 may emit light of different colors (e.g., red, green, and blue) to provide display 14 with the ability to display color images or may be monochromatic pixels.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry, such as control circuitry 16 of FIG. 1, over path 32. Path 32 may be formed from traces on a flexible printed circuit or other cable. During operation, the control circuitry (e.g., control circuitry 16 of FIG. 1) may supply display driver circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14.

Gate driver circuitry 34 (sometimes referred to as row control circuitry) may be implemented as part of an integrated circuit and/or may be implemented using thin-film transistor circuitry. Horizontal control lines G in display 14 may carry gate line signals such as scan line signals, emission enable control signals, and other horizontal control signals for controlling the display pixels 22 of each row. There may be any suitable number of horizontal control signals per row of pixels 22 (e.g., one or more row control signals, two or more row control signals, three or more row control signals, four or more row control signals, etc.).

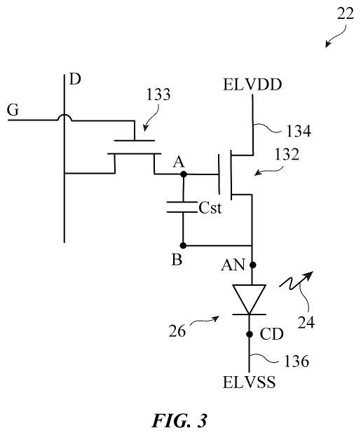

A schematic diagram of an illustrative pixel circuit of the type that may be used for each pixel 22 in display 14 is shown in FIG. 3. As shown in FIG. 3, display pixel 22 may include light-emitting diode 26. A positive power supply voltage ELVDD may be supplied to positive power supply terminal 134 and a ground power supply voltage ELVSS may be supplied to ground power supply terminal 136. Diode 26 has an anode (terminal AN) and a cathode (terminal CD). The state of drive transistor 132 controls the amount of current flowing through diode 26 and therefore the amount of emitted light 24 from display pixel 22. Cathode CD of diode 26 is coupled to ground terminal 136, so cathode terminal CD of diode 26 may sometimes be referred to as the ground terminal for diode 26.

To ensure that transistor 132 is held in a desired state between successive frames of data, display pixel 22 may include a storage capacitor such as storage capacitor Cst. The voltage on storage capacitor Cst is applied to the gate of transistor 132 at node A to control transistor 132. Data can be loaded into storage capacitor Cst using one or more switching transistors such as switching transistor 133. When switching transistor 133 is off, data line D is isolated from storage capacitor Cst and the gate voltage on terminal A is equal to the data value stored in storage capacitor Cst (i.e., the data value from the previous frame of display data being displayed on display 14). When gate line G (sometimes referred to as a scan line) in the row associated with display pixel 22 is asserted, switching transistor 133 will be turned on and a new data signal on data line D will be loaded into storage capacitor Cst. The new signal on capacitor Cst is applied to the gate of transistor 132 at node A, thereby adjusting the state of transistor 132 and adjusting the corresponding amount of light 24 that is emitted by light-emitting diode 26. If desired, the circuitry for controlling the operation of light-emitting diodes for display pixels in display 14 (e.g., transistors, capacitors, etc. in display pixel circuits such as the display pixel circuit of FIG. 3) may be formed using other configurations (e.g., configurations that include circuitry for compensating for threshold voltage variations in drive transistor 132, etc.). The display pixel may include additional switching transistors, emission transistors in series with the drive transistor, etc. Capacitor Cst may be positioned at other desired locations within the pixel (e.g., between the source and gate of the drive transistor). The display pixel circuit of FIG. 3 is merely illustrative.

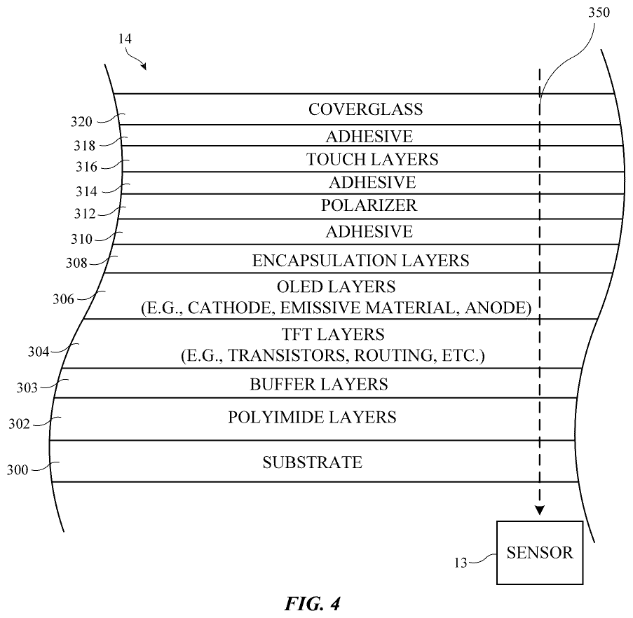

Device 10 may include a sensor 13 mounted behind display 14 (e.g., behind the active area of the display). FIG. 4 is a cross-sectional side view of an illustrative display stack of display 14 that at least partially covers a sensor in accordance with an embodiment. As shown in FIG. 4, the display stack may include a substrate such as substrate 300. Substrate 300 may be formed from glass, metal, plastic, ceramic, sapphire, or other suitable substrate materials. In some arrangements, substrate 300 may be an organic substrate formed from polyethylene terephthalate (PET) or polyethylene naphthalate (PEN) (as examples). One or more polyimide (PI) layers 302 may be formed over substrate 300. Polyimide layers 302 may sometimes be referred to as organic substrate 302 (e.g., substrate 300 is a first substrate layer and substrate 302 is a second substrate layer). The surface of substrate 302 may optionally be covered with one or more buffer layers 303 (e.g., inorganic buffer layers such as layers of silicon oxide, silicon nitride, amorphous silicon, etc.).

Thin-film transistor (TFT) layers 304 may be formed over inorganic buffer layers 303 and organic substrates 302 and 300. The TFT layers 304 may include thin-film transistor circuitry such as thin-film transistors, thin-film capacitors, associated routing circuitry, and other thin-film structures formed within multiple metal routing layers and dielectric layers. TFT layers 304 may be formed from inorganic material, if desired. Organic light-emitting diode (OLED) layers 306 may be formed over the TFT layers 304. The OLED layers 306 may include a diode cathode layer, a diode anode layer, and emissive material interposed between the cathode and anode layers. The OLED layers may include a pixel definition layer that defines the light-emitting area of each pixel. The TFT circuitry in layer 304 may be used to control an array of display pixels formed by the OLED layers 306.

Circuitry formed in the TFT layers 304 and the OLED layers 306 may be protected by encapsulation layers 308. As an example, encapsulation layers 308 may include a first inorganic encapsulation layer, an organic encapsulation layer formed on the first inorganic encapsulation layer, and a second inorganic encapsulation layer formed on the organic encapsulation layer. Encapsulation layers 308 formed in this way can help prevent moisture and other potential contaminants from damaging the conductive circuitry that is covered by layers 308. Substrate 300, polyimide layers 302, buffer layers 303, TFT layers 304, OLED layers 306, and encapsulation layers 308 may be collectively referred to as a display panel.

One or more polarizer films 312 (also referred to as polarizer 312 herein) may be formed over the encapsulation layers 308 using adhesive 310. Adhesive 310 may be implemented using optically clear adhesive (OCA) material that offer high light transmittance. One or more touch layers 316 that implement the touch sensor functions of touch-screen display 14 may be formed over polarizer films 312 using adhesive 314 (e.g., OCA material). For example, touch layers 316 may include horizontal touch sensor electrodes and vertical touch sensor electrodes collectively forming an array of capacitive touch sensor electrodes. Lastly, the display stack may be topped off with a cover glass layer 320 (sometimes referred to as a display cover layer 320) that is formed over the touch layers 316 using additional adhesive 318 (e.g., OCA material). Display cover layer 320 may be a transparent layer (e.g., transparent plastic or glass) that serves as an outer protective layer for display 14. The outer surface of display cover layer 320 may form an exterior surface of the display and the electronic device that includes the display.

It should be noted that polarizer 312 may be omitted from the display if desired.

The example in FIG. 4 of the display stack including OLED layers is merely illustrative. As previously noted, the display stack may include pixels formed using other display technology. For example, the display stack may include an array of discrete light-emitting diodes each formed from a crystalline semiconductor die (e.g., an array of microLEDs). Alternatively, the display stack may include a color filter layer over OLED layers 306 (e.g., on encapsulation layers 308). Additionally or alternatively, some of the layers shown in FIG. 4 may be partially or entirely omitted (e.g., polarizer 312) and/or additional layers may be added (e.g., additional polarizers). In general, display 14 may include any suitable layers.

Still referring to FIG. 4, sensor 13 may be formed under the display stack within the electronic device 10. As described above in connection with FIG. 1, sensor 13 may be an optical sensor (e.g., a light sensor) such as a camera, proximity sensor, ambient light sensor, fingerprint sensor, or other light-based sensor. In some cases, sensor 13 may include a light-emitting component that emits light through the display. Sensor 13 may therefore sometimes be referred to as input-output device 13. Input-output device 13 may be a sensor or a light-emitting component. The performance of input-output device 13 depends on the transmission of light traversing through the display stack, as indicated by arrow 350. A typical display stack, however, may alter the light passing through the display and may therefore interfere with measurements of the light taken by sensor 13.

Pixels 22 (FIG. 3) are generally formed in an array across display 14. In particular, due to manufacturing and cost considerations, displays are often formed with uniform (or near uniform) pixels across the display. For example, all of the pixels may have the same circuitry (e.g., TFT circuitry), signal line shape and size, display layer layout, etc. However, having pixels overlapping sensor 13 may reduce the light received by sensor 13. Therefore, the pixels overlapping sensor 13 may be modified to form a window through which light may be transmitted to sensor 13.

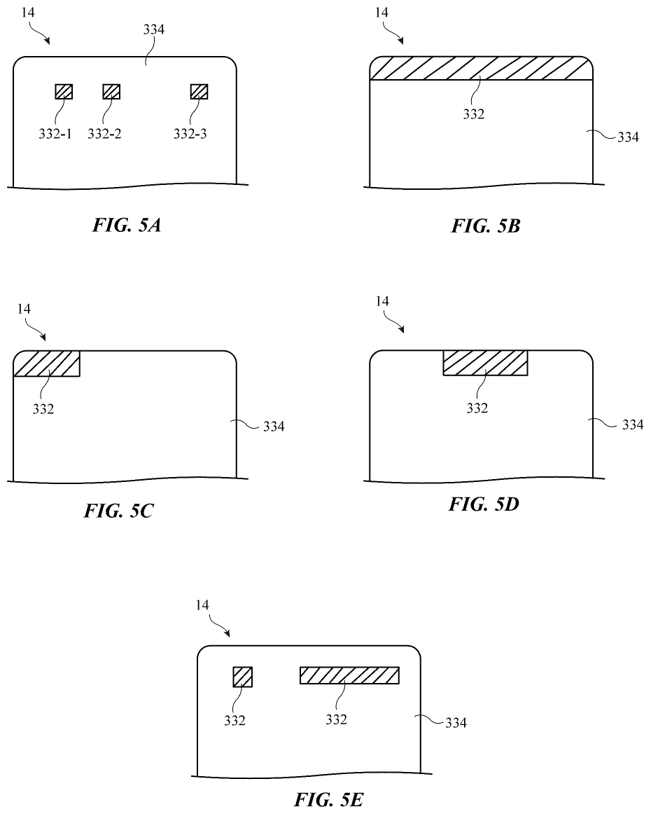

In general, the display may be modified to form window(s) in any region(s) of display 14. FIGS. 5A-5E are front views showing how display 14 may have one or more locally modified regions in which the display is modified to form windows for one or more underlying sensors. The example of FIG. 5A illustrates various windows 332 physically separated from one another (i.e., the various windows 332 are non-continuous) by normal display region 334. The windows 332 may have some modification (e.g., the pixel(s) in windows 332 may be modified) relative to normal display region 334 to form windows that allow the transmission of light to an underlying sensor. The normal display region 334 may be unmodified (e.g., include pixels that are unmodified) and therefore may be referred to as unmodified region 334 herein.

The three windows 332-1, 332-2, and 332-3 in FIG. 5A might for example correspond to three different sensors formed underneath display 14 (with one sensor per window). Any portion of the display that is within the field-of-view of an underlying sensor may be modified.

The example of FIG. 5B illustrates a continuous window 332 formed along the top border of display 14, which might be suitable when there are many optical sensors positioned near the top edge of device 10. The example of FIG. 5C illustrates a window 332 formed at a corner of display 14 (e.g., a rounded corner area of the display). In some arrangements, the corner of display 14 in which window 332 is located may be a rounded corner (as in FIG. 5C) or a corner having a substantially 90° corner. The example of FIG. 5D illustrates a window 332 formed only in the center portion along the top edge of device 10 (e.g., the window covers a recessed notch area in the display). FIG. 5E illustrates another example in which windows 332 can have different shapes and sizes. These examples are merely illustrative and are not intended to limit the scope of the present embodiments. If desired, one or more windows may be formed in any one or more portions of the display overlapping optical sensors or other sub-display electrical components.

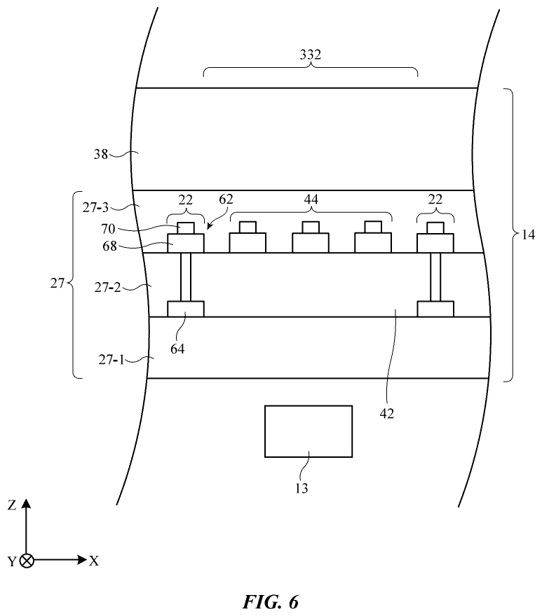

An illustrative example of modifying pixels that overlap a sensor to form a window is shown in FIG. 6. As shown in FIG. 6, display 14 may include an array of display pixels 22 (also referred to as pixels 22 herein). Each display pixel 22 may include emissive subpixel 62 (also referred to as emissive pixel portion 62 or emissive portion 62 herein) and thin-film transistor driver 64 (also referred to as TFT driver 64 or TFT subpixel 64 herein). Thin-film transistor drivers 64 are formed within substrate 27. Substrate 27 may include one or more dielectric layers (such as layers 27-1, 27-2, and 27-3) and metallization layers that form the thin-film transistor circuitry (e.g., thin-film transistor drivers 64) that operates the display. Thin-film transistor drivers 64 are formed on dielectric layer 27-1. Each thin-film transistor driver 64 of each pixel 22 is electrically connected to and controls a respective emissive portion 62 of that pixel 22. In the example of FIG. 6, each emissive portion 62 includes a respective anode 68 and OLED layers 70 (e.g., a hole injection layer, hole transport layer, an emissive layer, a charge generation layer, an electron transport layer, an electron injection layer, and/or other OLED layers). For example, emissive portion 62 may correspond with OLED layers 306 (FIG. 4), and TFT driver 64 may correspond with TFT layers 304 (FIG. 4). However, this example is merely illustrative. In general, each emissive subpixel may be formed using any desired type of display technology (e.g., OLED, LED, LCD, microLED, etc.), and each emissive subpixel may include anodes for the pixels, OLED layers for the pixels, pixel definition layers for the pixels, and/or any other suitable emissive/display layers.

Thin-film transistor drivers 64 may control the light emitted from the associated emissive portion 62 in each pixel 22. Each pixel 22, and therefore each emissive portion 62 and thin-film transistor driver 64, may be associated with a different color of light (e.g., red, green, and blue). In some embodiments, however, multiple emissive portions 62 may be driven by a single TFT driver 64, and/or each emissive portion 62 may be drive by multiple TFT drivers 64. The emissive subpixel for a given pixel does not necessarily need to have the same footprint as its associated thin-film transistor driver (e.g., the emissive subpixel may be smaller or larger than the associated thin-film transistor driver).

As shown in FIG. 6, each emissive subpixel 62 vertically overlaps (e.g., in the Z-direction) a respective thin-film transistor driver 64 by which it is controlled. However, this is merely illustrative. In some embodiments, at least some of pixels 22 may have emissive subpixels 62 that are offset (e.g., in the +X or −X direction) from the associated thin-film transistor driver 64.

Sensor 13 may be formed behind (e.g., under) display 14. In other words, sensor 13 may be overlapped by display 14 in the Z-direction. In particular, sensor 13 may receive and/or emit light through display 14. For example, sensor 13 may be a camera that receives light through display 14. In general, however, sensor 13 may be any suitable sensor that operates through display 14.

Window 332 may be formed in display 14 and may overlap sensor 13. Window 332 may be formed by removing one or more TFT drivers 64 and driving the associated emissive subpixels 62 using distributed TFT drivers. In particular, as shown in FIG. 6, the TFT driver of pixel 44 has been removed to form TFT subpixel-free region 42, which in turn may form window 332. The TFT subpixel-free region 42 of window 332 may allow light to pass without diffracting or distorting the light. However, the emissive portion of pixel 44 is still present within window 332, which may allow display 14 to have a uniform appearance. In this way, window 332 may be formed to allow sensor 13 to operate through display 14 without sacrificing the appearance of display 14.

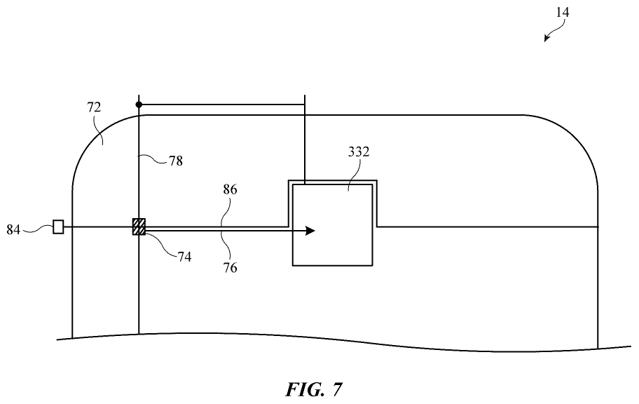

The pixels in window 332 (e.g., pixels 44) may be coupled to distributed thin-film transistor drivers, which may be TFT drivers that are remote from window 332 and that are coupled to pixels 44 (e.g., to drive the emissive portions of pixels 44). For example, the distributed TFT drivers may be distributed within a light-emitting area (e.g., the active area) of display 14 and/or may be distributed along an edge of the light-emitting area. An illustrative example of remote TFT drivers that are distributed in the light-emitting area is shown in FIG. 7.

As shown in FIG. 7, display 14 may include light-emitting area 72. Light-emitting area 72 may include a plurality of pixels, such as pixels 22 of FIG. 2. Window 332 may be formed in light-emitting area 72. For example, window 332 may overlap a sensor, such as sensor 13 of FIG. 6.

To allow light to reach the underlying sensor, the pixels in window 332 may have removed TFT drivers (e.g., TFT subpixels/pixels). In other words, the pixels in window 332 may include a subset of the emissive portions/subpixels of light-emitting area 72 (e.g., those emissive portions/subpixels present in window 332), but window 332 may be free from TFT drivers.

To drive the emissive portions of the pixels in window 332, TFT drivers associated with the emissive subpixels in window 332 may be distributed within the other portions of light-emitting area 72 (e.g., the rest of light-emitting area 72 not including window 332, show as unmodified region 334 of FIG. 5). For example, TFT driver 74 may be formed in light-emitting area 72, outside of window 332, and may be coupled to one or more pixels in window 332 (e.g., the subset of the emissive portions of light-emitting area 72 that are associated with the pixels in window 332) via line 76. For example, TFT driver 74 may be coupled to at least one pixel, at least 10 pixels, at least 20 pixels, at least 30 pixels, at least 40 pixels, between 20 and 40 pixels, or another suitable number of pixels in window 332.

TFT driver 74 may be coupled to data line 78 and may receive signals (e.g., signals from control circuitry, such as control circuitry 16 of FIG. 1) over data line 78. In response to these signals, TFT driver 74 may drive the one or more pixels (e.g., the emissive portions of one or more pixels or subpixels) in window 332 to which TFT driver 74 is coupled.

Gate driver 84 may be formed outside of light-emitting area 72, if desired, and may be coupled to one or more pixels in window 332 via line 86.

In the illustrative example of FIG. 7, window 332 has a square or rectangular shape. However, this is merely illustrative. In general, window 332 may have any desired shape, such as a circular shape, an oval shape, a pentagonal shape, a hexagonal shape, a freeform shape, etc.

Although FIG. 7 shows a single TFT driver 74, TFT drivers 74 that are coupled to pixels in window 332 may be distributed throughout light-emitting area 72. Therefore, TFT drivers 74 may be referred to as distributed thin-film transistor drivers 74 herein. For example, at least ten TFT drivers, at least 20 TFT drivers, at least 50 TFT drivers, or at least 100 TFT drivers, as examples, may be distributed through light-emitting area 72 and coupled to one or more pixels in window 332. These TFT drivers may be distributed evenly/uniformly across light-emitting area 72 to maintain the uniformity of display 14. In other words, an equal number of pixels (e.g., pixels 22 of FIG. 2) may be formed between each distributed TFT driver 74. The distributed TFT drivers for the pixels in window 332 may be distributed uniformly across an entirety of light-emitting area 72, or across one or more portions of light-emitting area 72.

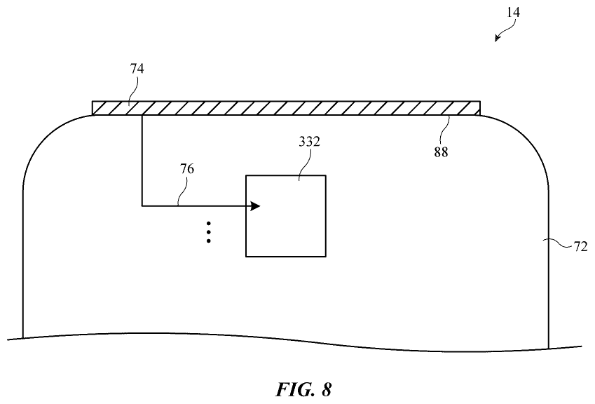

Instead of, or in addition to, distributing TFT drivers in the light-emitting area, remote/distributed TFT drivers may be distributed along an edge of the light-emitting area. An illustrative example is shown in FIG. 8.

As shown in FIG. 8, one or more TFT drivers 74 may be distributed along edge 88 of light-emitting area 72. In other words, TFT drivers 74 may be formed just outside of light-emitting area 72, along edge 88. TFT drivers 74 may be formed in a single row along edge 88, in at least two rows along edge 88, or in any other suitable number of rows along edge 88.

One or more TFT drivers 74 may be coupled to one or more pixels in window 332 (e.g., the subset of the emissive portions of light-emitting area 72 that are associated with the pixels in window 332) via line 76. In general, any suitable number of lines 76 may run between the group of TFT drivers 74 to the pixels in window 332. The lines 76 may be routed to one side of window 332 or may be routed to multiple sides of window 332.

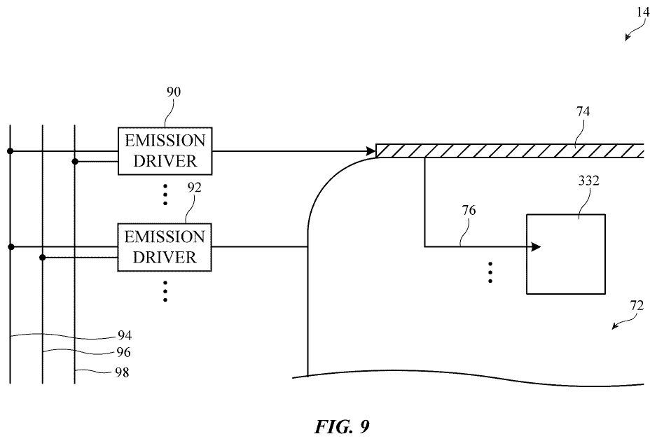

Regardless of whether TFT drivers 74 are distributed in light-emitting area 72 or along an edge of light-emitting area 72, TFT drivers 74 may be driven differently from other TFT drivers in light-emitting area 72 to ensure that the appearance of window 332 matches the appearance of the rest of light-emitting area 72. An illustrative example is shown in FIG. 9.

As shown in FIG. 9, TFT drivers 74 may be coupled to one or more dedicated emission drivers 90, while emission drivers 92 drive the pixels in the rest of light-emitting area 72. Emission driver(s) 90 may be coupled to reset voltage line 94 and to clock line(s) 98, while emission driver(s) 92 may be coupled to reset voltage line 94 and clock line(s) 96. By coupling TFT drivers 74 to dedicated emission driver(s) 90, TFT drivers 74 may be driven differently (e.g., with a different timing/frequency) than the rest of the pixels in light-emitting area 72. For example, the pixels in window 332 may be blanked to allow sensor 13 to operate, and driving the pixels in window 332 with a different timing/frequency may allow window 332 to have an appearance that matches the appearance of the rest of the display, despite the additional blanking time. In this way, display 14 may have a uniform appearance despite the physical difference of the modified pixels in window 332.

Emission driver(s) 90 and/or emission driver(s) 92 may be single-stage emission drivers and/or multistage emission drivers. Alternatively or additionally, although emission drivers 90 and 92 have been described as being coupled to different clock lines, this is merely illustrative. If desired, emission drivers 90 and 92 may share clock lines.

Although FIG. 9 shows dedicated emission driver(s) 90 coupled to TFT drivers 74, this is merely illustrative. In general, any suitable dedicated row drivers, such as scan drivers, may be coupled to TFT drivers 74 to drive the pixels in window 332 differently from the pixels in the rest of light-emitting area 72. In this way, display 14 may have a uniform appearance despite the physical difference of the modified pixels in window 332.

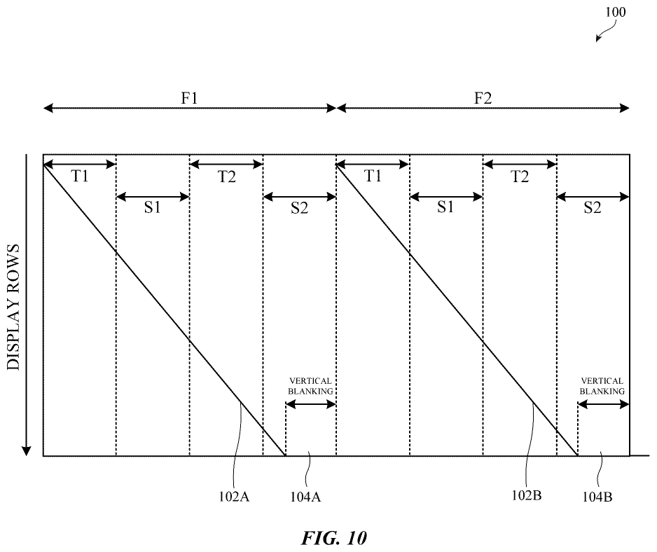

By driving TFT subpixels 74 with dedicated drivers, such as emission driver(s) 90, the pixels in window 332 may be driven with a different frequency from the frequency at which the rest of the pixels in light-emitting area 72 are driven. An illustrative example is shown in FIG. 10.

As shown in FIG. 10, timing diagram 100 may include first frame F1 and second frame F2. As indicated by lines 102A and 102B, all of the rows of the display (e.g., display 14) emit light/images during each frame (e.g., frame F1 and frame F2). Times T1 and T2 of frames F1 and F2 may correspond to times in which the pixels in a sensor window (e.g., window 332) are being driven. For example, in the embodiment of FIG. 9, emission driver(s) 90 may drive the pixels in window 332 to emit images during times T1 and T2. During times S1 and S2, on the other hand, the pixels in the sensor window may not be driven. For example, in the embodiment of FIG. 9, emission driver(s) 90 may not drive additional pixels in window 332 during times S1 and S2. Instead, the underlying sensor (e.g., sensor 13) may be on during times S1 and S2. In this way, light from the pixels in window 332 may not interfere (or interfere less) with the measurements of sensor 13.

The rest of the pixels in light-emitting area 72 (e.g., the pixels not in window 332) may be driven (e.g., by emission driver(s) 92) during the entirety of frame F1 and F2, except for vertical blanking times 104A and 104B.

In some embodiments, the pixels in window 332 may be driven with a different frequency than the rest of the pixels in light-emitting area 72. As an illustrative example, the pixels in window 332 may be driven with a frequency of 120 Hz or 90 Hz, and the rest of the pixels in light-emitting area 72 may be driven with a different frequency, such as a frequency of 90 Hz or 60 Hz. However, the pixels in window 332 may be driven with the same frequency as the rest of the pixels in light-emitting area 72, if desired.

Although the example of FIG. 10 shows times T1 and T2 in which the pixels in window 332 are driven as being at the beginning and middle of each frame F1 and F2, this is merely illustrative. In general, times T1 and T2 in which the pixels in window 332 are driven may be at the beginning, middle, and/or end of each frame.

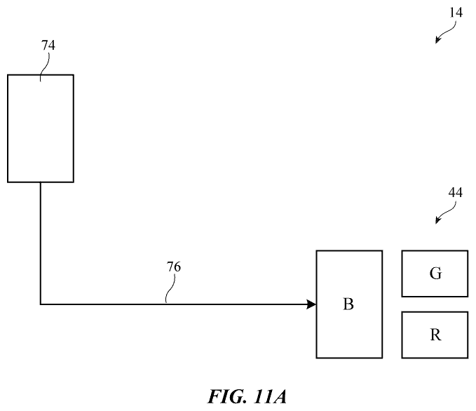

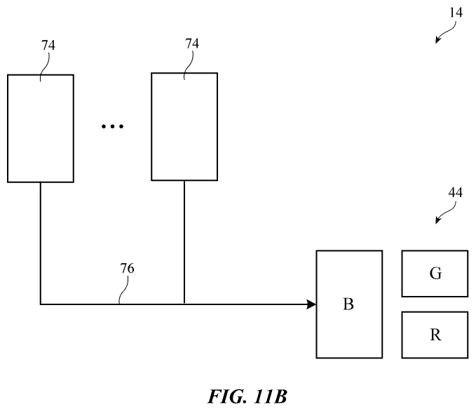

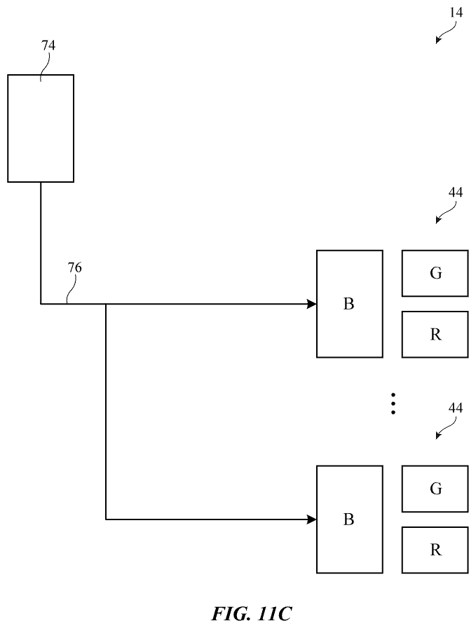

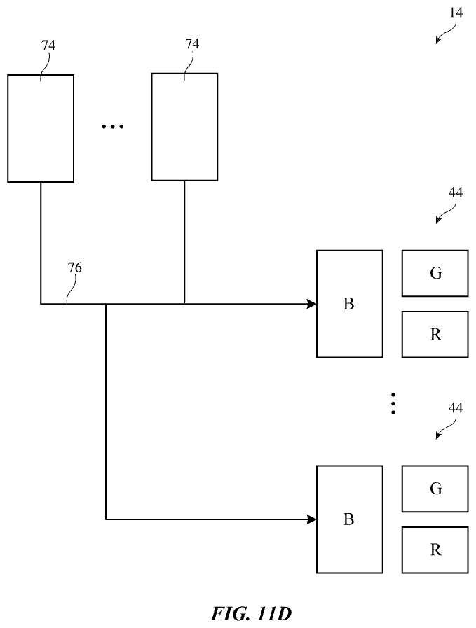

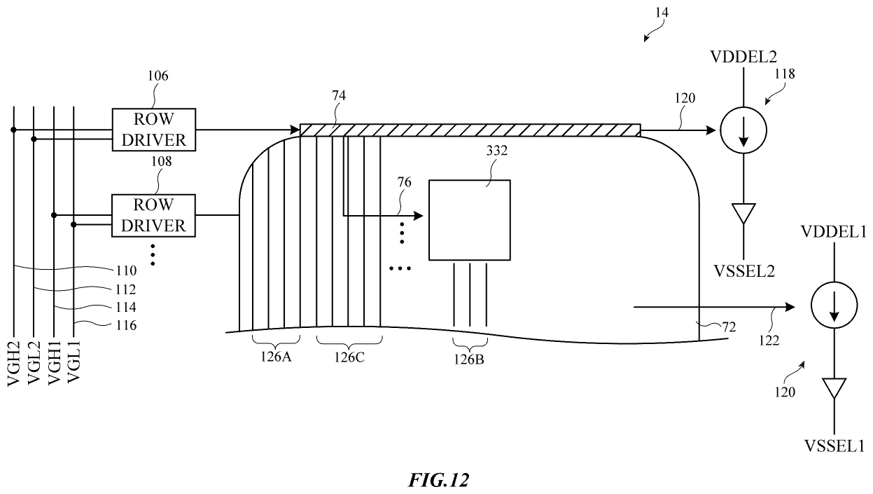

In general, each of the distributed/remote TFT drivers may be coupled to any suitable number of the pixels in window 332. Illustrative examples are shown in FIG. 11A-11D.

As shown in FIG. 11A, each TFT driver 74 may be coupled to a single pixel 44 of window 332. In other words, each TFT driver 74 may be coupled to emissive portion(s) associated with a single pixel of the window.

As shown in FIG. 11B, multiple TFT drivers 74 may be coupled to a single pixel 44 of window 332. In other words, multiple TFT drivers 74 may be coupled to emissive portion(s) associated with a single pixel of the window.

As shown in FIG. 11C, each TFT driver 74 may be coupled to multiple pixels 44 of window 332. In other words, each TFT driver 74 may be coupled to emissive portion(s) associated with multiple pixels of the window, such as at least two pixels of the window, at least three pixels of the window, at least five pixels of the window, or any other suitable number of pixels of the window.

As shown in FIG. 11D, multiple TFT drivers 74 may be coupled to multiple pixels 44 of window 332. In other words, multiple TFT drivers 74 may be coupled to emissive portion(s) associated with multiple pixels of the window. For example, at least two TFT drivers, at least three TFT drivers, at least five TFT drivers, or another suitable number of TFT drivers may be coupled to at least two pixels of the window, at least three pixels of the window, at least five pixels of the window, or any other suitable number of pixels of the window.

Regardless of the number of remote/distributed TFT drivers coupled to each pixel in a sensor window, the TFT drivers may be coupled to dedicated power domains. An illustrative example is shown in FIG. 12.

As shown in FIG. 12, TFT drivers 74 may be coupled to dedicated power domains, including dedicated VDDEL/VSSEL power domain 118 and dedicated row driver(s) 106. In particular, TFT drivers 74 may be coupled to VDDEL/VSSEL power domain 118 that includes VDDEL2 and VSSEL2, while the rest of the pixels in light-emitting area 72 may be coupled to VDDEL/VSSEL power domain 129 that includes VDDEL1 and VSSEL1. VDDEL2 and VSSEL2 may be different from VDDEL1 and VSSEL1, providing TFT drivers 74 with a dedicated power domain.

Additionally or alternatively, TFT drivers 74 may be coupled to dedicated row driver(s) 106, while the rest of the pixels in light-emitting area 72 may be coupled to row driver(s) 108. Dedicated row driver(s) 106 may be coupled to power lines VGH2 and VGL2, while row driver(s) 108 may be coupled to power lines VGH1 and VGL1. VGH2 and VGL2 may be different from VGH1 and VGL1, providing dedicated row driver(s) 106, and therefore TFT drivers 74, with a dedicated power domain.

By providing TFT drivers 74 with one or more dedicated power domains, the voltage/current provided to TFT drivers 74 may be increased, boosting the peak luminance of the pixels in window 332. In this way, the light emitted by the pixels in window 332 may be adjusted to match the light emitted by the pixels in the rest of light-emitting area 72, such as by increasing the brightness of the pixels in window 332, providing a more uniform display.

As shown in FIG. 12, vertical data lines 126 carry data information of image content to the TFT drivers of the pixels in display 14. In particular, each of vertical data lines 126A carries data information of image content to columns of pixels in light-emitting area 72. In contrast, because TFT drivers 74 for the pixels in window 332 are located outside of light-emitting area 72, data lines 126B may not carry data information to the TFT drivers for the pixels in window 332, despite being aligned in the same column as the pixels in window 332. Instead, other data lines, such as data lines 126C, may carry data information to TFT drivers 74 for the pixels in window 332. In other words, data lines 126C may carry the data information to TFT drivers 74 for the pixels in window 332, as well as the data information to TFT drivers in columns of pixels in light-emitting area 72 that correspond with data lines 126C.

To account for data lines 126C carrying the data information to TFT drivers 74 for pixels in window 332, the data information that would typically be carried by data lines 126B to the pixels in window 332 may be remapped. In other words, the data information for pixels 332 may be remapped and carried over data lines 126C to TFT drivers 74. This data remapping may be performed by control circuitry, such as a display driver integrated circuit (DDIC) and/or a system on chip (SOC), to ensure that the correct image data is displayed by the correct pixels in window 332. Additionally, the control circuitry may synchronize the remapped image data with row driver timing so images in window 332 match the images in the rest of light-emitting area 72.

Although FIGS. 8, 9, and 12 show vertically oriented display 14 with TFT drivers 74 along upper edge 88 of light-emitting area 72, this is merely illustrative. In general, display 14 may be oriented in any suitable direction (e.g., horizontally), and TFT drivers 74 may be formed along one or more edges of light-emitting area 72.

As described above, one aspect of the present technology is the gathering and use of information such as information from input-output devices. The present disclosure contemplates that in some instances, data may be gathered that includes personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, username, password, biometric information, or any other identifying or personal information.

The present disclosure recognizes that the use of such personal information, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the United States, collection of or access to certain health data may be governed by federal and/or state laws, such as the Health Insurance Portability and Accountability Act (HIPAA), whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, the present technology can be configured to allow users to select to “opt in” or “opt out” of participation in the collection of personal information data during registration for services or anytime thereafter. In another example, users can select not to provide certain types of user data. In yet another example, users can select to limit the length of time user-specific data is maintained. In addition to providing “opt in” and “opt out” options, the present disclosure contemplates providing notifications relating to the access or use of personal information. For instance, a user may be notified upon downloading an application (“app”) that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of information that may include personal information data to implement one or more various disclosed embodiments, the present disclosure also contemplates that the various embodiments can also be implemented without the need for accessing personal information data. That is, the various embodiments of the present technology are not rendered inoperable due to the lack of all or a portion of such personal information data.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
a plurality of pixels arranged in a light-emitting area, wherein each one of the plurality of pixels includes an emissive portion and a thin-film transistor driver that controls the emissive portion of that pixel;
a window in the plurality of pixels that includes a subset of the emissive portions and that is free of thin-film transistor drivers;
distributed thin-film transistor drivers that are coupled to the subset of the emissive portions to control the subset of the emissive portions, wherein the distributed thin-film transistor drivers are distributed along an edge of the light-emitting area. ; and
an optical sensor that operates through the window in the plurality of pixels.

2. The electronic device of claim 1, wherein the distributed thin-film transistor drivers comprise one or more rows of thin-film transistor drivers along the edge of the light-emitting area.

3. The electronic device of claim 2, further comprising:
emission drivers coupled to the thin-film transistor drivers of the plurality of pixels in the light-emitting area; and
dedicated emission drivers coupled to the distributed thin-film transistor drivers.

4. The electronic device of claim 3, wherein the emission drivers are configured to drive the plurality of pixels with a first frequency and the dedicated emission drivers are configured to drive the subset of the emissive portions with a second frequency that is different from the first frequency.

5. The electronic device of claim 4, wherein the second frequency is greater than the first frequency.

6. The electronic device of claim 2, wherein each of the distributed thin-film transistor drivers is coupled to a respective one of the emissive portions of the subset of the emissive portions.

7. The electronic device of claim 2, wherein at least two of the distributed thin-film transistor drivers is coupled to each of the emissive portions of the subset of the emissive portions.

8. The electronic device of claim 2, wherein each of the distributed thin-film transistor drivers is coupled to at least two of the emissive portions of the subset of the emissive portions.

9. The electronic device of claim 2, further comprising:
row drivers coupled to the thin-film transistor drivers of the plurality of pixels in the light-emitting area; and
dedicated row drivers coupled to the distributed thin-film transistor drivers.

10. The electronic device of claim 2, further comprising:
a power domain coupled to the thin-film transistor drivers of the plurality of pixels in the light-emitting area; and
a dedicated power domain coupled to the distributed thin-film transistor drivers.

11. An electronic device, comprising:
a light sensor; and
a display comprising a plurality of pixels that form a light-emitting area, wherein the light sensor is configured to sense light that passes through the display, the display has a first region that overlaps the light sensor and a second region that does not overlap the light sensor, and the plurality of pixels in the first region include emissive portions that are coupled to distributed thin-film transistor drivers along an edge of the light-emitting area.

12. The electronic device of claim 11, further comprising:
dedicated emission drivers coupled to the distributed thin-film transistor drivers.

13. The electronic device of claim 12, wherein the dedicated emission drivers are configured to drive the emissive portions in the first region with a first frequency, and the plurality of pixels in the second region are configured to be driven with a second frequency that is different from the first frequency.

14. The electronic device of claim 11, wherein at least two of the distributed thin-film transistor drivers are coupled to each of the emissive portions in the first region of the plurality of pixels.

15. The electronic device of claim 11, further comprising:
dedicated row drivers coupled to the distributed thin-film transistor drivers.

16. The electronic device of claim 11, further comprising:
a dedicated power domain coupled to the distributed thin-film transistor drivers.

17. An electronic device, comprising:
a plurality of pixels arranged in a light-emitting area, wherein each one of the plurality of pixels includes an emissive subpixel and a thin-film transistor driver that controls the emissive subpixel of that pixel;
a window in the plurality of pixels that includes a subset of the emissive subpixels and that is free of thin-film transistor drivers;
distributed thin-film transistor drivers that are coupled to the subset of the emissive subpixels to control the subset of the emissive subpixels, wherein the distributed thin-film transistor drivers are formed along an edge of the light-emitting area; and
a sensor that operates through the window in the plurality of pixels.

18. The electronic device of claim 17, further comprising:
dedicated emission drivers coupled to the distributed thin-film transistor drivers;
dedicated row drivers coupled to the distributed thin-film transistor drivers; and
a dedicated power domain coupled to the distributed thin-film transistor drivers.

19. The electronic device of claim 18, further comprising:
first data lines coupled to the pixels outside of the window, wherein the first data lines are vertical data lines; and
second data lines coupled to the subset of the distributed thin-film transistor drivers and to some of the pixels outside of the window.

20. The electronic device of claim 19, further comprising:
control circuitry configured to remap image data for the distributed thin-film transistor drivers over the second data lines and to synchronize the remapped image data to match images in the window to images outside of the window.
